(19) United States
(12) Patent Application Publication
(10) Pub. No.: US 2025/0311508 A1
(43) Pub. Date: Oct. 2, 2025

(54) LED DISPLAY DEVICE COMPRISING STACKED MICRO-LED ELEMENTS AND METHOD FOR MANUFACTURING SAME

(71) Applicant: ADVANCED VIEW TECHNOLOGY INC., Ansan-si, Gyeonggi-do (KR)

(72) Inventor: Jung-Geun JHIN, Ansan-si, Gyeonggi-do (KR)

(73) Assignee: ADVANCED VIEW TECHNOLOGY INC., Ansan-si, Gyeonggi-do (KR)

(21) Appl. No.: 18/864,005

(22) PCT Filed: Mar. 13, 2023
(86) PCT No.: PCT/KR2023/003375

§ 371 Date: Nov. 8, 2024

(30) Foreign Application Priority Data
May 9, 2022 (KR) 10-2022-0056800

(51) Int. Cl. H10H 29/851; H01L 25/075; H10H 29/01; H10H 29/32; H10H 29/49

(52) U.S. Cl. CPC H10H 29/8512; H01L 25/0756; H10H 29/032; H10H 29/0364; H10H 29/32; H10H 29/49

(57) ABSTRACT

A light emitting diode (LED) display device includes: a first electrode layer and a second electrode layer disposed to be spaced apart from each other on a substrate; a plurality of micro-LED elements stacked in a longitudinal direction to be parallel to a plane of the substrate on the first electrode layer and the second electrode layer and stacked to be spaced apart from each other; and a first connection electrode coupled to both ends of the plurality of micro-LED elements and extending from one ends of the plurality of micro-LED elements to the first electrode layer and a second connection electrode extending from the other ends of the plurality of micro-LED elements to the second electrode layer and connected to the second electrode layer.

### CROSS-REFERENCE TO PRIOR APPLICATIONS

This Application is a National Stage Patent Application of PCT International Application No. PCT/KR2023/003375 (filed on Mar. 13, 2023), which claims priority to Korean Patent Application No. 10-2022-0056800 (filed on May 9, 2022), which are all hereby incorporated by reference in their entirety.

### BACKGROUND

The present invention relates to an LED display device and resolution and a method of manufacturing the same, which can improve brightness and resolution by stacking micro-LED elements to be spaced apart from each other so that a longitudinal direction of the micro-LED element is parallel to a plane of a substrate and integrating a large number of micro-LED elements compared to an area.

Display devices may display a screen by a plurality of pixels that constitute a panel. Each pixel may be divided into sub-pixels that emit a single color of R (Red), G (Green), and B (Blue) and may express all colors from true black to white depending on the intensity of light of each of R, G, and B.

To express all colors, at least one micro-light emitting diode (LED) element capable of expressing each of R, G, and B is required for one pixel.

The micro-LED element is generally an LED whose one side has a length of 100 μm or less. This corresponds to a size of about 1/10 or less compared to a general LED element.

Since the micro-LED element is formed based on an inorganic material such as GaN or AlGaInP, the micro-LED element is known to have excellent durability. In addition, the micro-LED element has an advantage of low heat generation and power consumption due to its small size.

The micro-LED element may be disposed in a horizontal structure between electrodes on a substrate to form one pixel PXL (light source). For example, when a driving current flows in a pixel, the micro-LED elements connected between the electrodes may emit light.

In this way, when the micro-LED elements emit light, the display device may display a screen.

However, when a defective product occurs among the disposed micro-LED elements or a micro-LED element is not present at a location where the micro-LED element needs to be located due to poor transfer, there may be a problem that the resolution of the display device is reduced. In addition, since there is a limit to the number of micro-LED elements that may be arranged per unit area of a pixel, it may be difficult to exhibit excellent light efficiency of the display device, and there is a disadvantage that it is necessary to increase brightness while consuming more area of the pixel.

Therefore, there is a need for research on a display device that can improve brightness and resolution compared to the display device in which the micro-LED elements are disposed only in the horizontal structure with respect to the substrate and allow pixels to emit light even when defective micro-LED elements or poor transfer occurs.

### SUMMARY

The present invention is directed to providing a method of manufacturing a light emitting diode (LED) display device, which can improve brightness and resolution by integrating a number of micro-LED elements per unit area of a pixel.

In addition, the present invention is directed to providing a method of manufacturing an LED display device, which can increase luminous efficiency without consuming more area of a pixel.

In addition, the present invention is directed to providing a method of manufacturing an LED display device, which allows a pixel to emit light even when defective pixels or poor transfer occurs.

In addition, the present invention is directed to providing a method of manufacturing an LED display device, which can minimize an interference phenomenon between pixels and enhance the directivity of light in the pixel.

In addition, the present invention is directed to providing a method of manufacturing an LED display device, which may align one micro-LED element in one groove.

In addition, the present invention is directed to providing a method of manufacturing an LED display device, which may form connection electrodes having a regular shape as much as possible at once and have a simple process.

In addition, the present invention is directed to providing an LED display device that is manufactured according to the manufacturing method and formed by stacking a plurality of micro-LED elements in a state in which a longitudinal direction of the micro-LED element is parallel to a plane of a substrate.

Objects of the present invention are not limited to the above-described objects, and other objects and advantages of the present invention which are not mentioned can be understood by the following description and more clearly understood by embodiments of the present invention. In addition, it will be able to be easily seen that the objects and advantages of the present invention may be achieved by devices and combinations thereof that are described in the claims.

A method of manufacturing a light emitting diode (LED) display device according to the present invention may include (a) forming a first insulating layer on a substrate on which a first electrode layer and a second electrode layer are disposed to be spaced apart from each other, (b) aligning a first micro-LED element on the first insulating layer corresponding to a region between the first electrode layer and the second electrode layer so that a longitudinal direction of the first micro-LED element is parallel to a plane of the substrate, (c) forming a second insulating layer on the substrate on which the first micro-LED element is aligned, (d) aligning a second micro-LED element on the second insulating layer corresponding to the region between the first electrode layer and the second electrode layer so that a longitudinal direction of the second micro-LED element is parallel to the plane of the substrate, and (e) patterning the first insulating layer and the second insulating layer so that the first electrode layer and the second electrode layer are exposed, and then depositing a first connection electrode to one ends of a plurality of stacked micro-LED elements and depositing a second connection electrode to the other ends to connect the plurality of stacked micro-LED elements to the first electrode layer and the second electrode layer.

The operation (b) may include (b1) forming one or more first grooves in a region between the first electrode layer and the second electrode layer of the first insulating layer, and (b2) aligning one first micro-LED element in one first groove so that the longitudinal direction of the first micro-LED element is parallel to the plane of the substrate.

The operation (d) may include (d1) forming one or more second grooves in a region between the first electrode layer and the second electrode layer of the second insulating layer, and (d2) aligning one second micro-LED element in one second groove so that the longitudinal direction of the second micro-LED element is parallel to the plane of the substrate.

In addition, forming an insulating layer and aligning the micro-LED element on the insulating layer corresponding to the region between the first electrode layer and the second electrode layer so that the longitudinal direction of the micro-LED element is parallel to the plane of the substrate may be performed one or more times between the operation (d) and the operation (e).

The operation (e) may be performed in one of two methods. A first method may include (e1) applying photoresist on the substrate on which the plurality of stacked micro-LED elements are disposed and then removing portions of the photoresist corresponding to both ends of the plurality of micro-LED elements, (e2) removing portions of the first insulating layer and the second insulating layer corresponding to the both ends of the plurality of micro-LED elements so that the first electrode layer and the second electrode layer are exposed, (e3) depositing the first connection electrode to extend from the one ends of the plurality of micro-LED elements to the first electrode layer and depositing the second connection electrode to extend from the other ends to the second electrode layer to connect the one ends of the plurality of micro-LED elements to the first electrode layer and connect the other ends of the plurality of micro-LED elements to the second electrode layer, and (e4) removing all of the first insulating layer, the second insulating layer, and the photoresist.

A second method may include (e1) applying first photoresist on the substrate on which the plurality of stacked micro-LED elements are disposed and then removing portions of the first photoresist corresponding to both ends of the plurality of micro-LED elements, (e2) removing portions of the first insulating layer and the second insulating layer corresponding to the both ends of the plurality of micro-LED elements so that the first electrode layer and the second electrode layer are exposed and then removing the first photoresist, (e3) depositing a connection electrode on the entire surface of the substrate on which the plurality of micro-LED elements are disposed to connect the ones of the plurality of micro-LED elements to the first electrode layer and connect the other ends of the plurality of micro-LED elements to the second electrode layer, (e4) applying second photoresist on the substrate on which the connection electrode is deposited and applying the second photoresist on upper portions and side surfaces of the plurality of micro-LED elements, and (e5) removing the first insulating layer, the second insulating layer, and the connection electrode from a portion where the second photoresist is not applied and then removing the remaining second photoresist, the first insulating layer, and the second insulating layer.

A light emitting diode (LED) display device according to the present invention may include a first electrode layer and a second electrode layer disposed to be spaced apart from each other on a substrate, a plurality of micro-LED elements stacked in a longitudinal direction to be parallel to a plane of the substrate on the first electrode layer and the second electrode layer and stacked to be spaced apart from each other, and a first connection electrode coupled to both ends of the plurality of micro-LED elements and extending from one ends of the plurality of micro-LED elements to the first electrode layer and a second connection electrode extending from the other ends of the plurality of micro-LED elements to the second electrode layer and connected to the second electrode layer.

The micro-LED element may have a nanowire shape.

According to the method of manufacturing an LED display device of the present invention, it is possible to improve brightness and resolution by integrating a number of micro-LED elements per unit area.

In addition, according to the manufacturing method, it is possible to increase luminous efficiency without consuming more area of the pixel.

In addition, according to the manufacturing method, there is an advantage that the pixel emits light even when defective pixels or poor transfer occurs.

In addition, according to the manufacturing method, it is possible to minimize the interference phenomenon between the pixels and enhance the directivity of light in the pixel.

In addition, according to the manufacturing method, it is possible to align one micro-LED element in one groove.

In addition, according to the manufacturing method, it is possible to form the connection electrodes having a regular shape as much as possible using a one-step process and have a simple process.

The LED display device manufactured according to the manufacturing method can have the structure in which the plurality of micro-LED elements are stacked in the state in which the longitudinal direction of the micro-LED element is parallel to the plane (bottom surface) of the substrate and thus have better brightness and resolution.

Specific effects together with the above-described effects are described together with a description of the following detailed matters for carrying out the disclosure.

### BRIEF DESCRIPTION OF THE DRAWINGS

FIG. 1 is a flowchart showing a method of manufacturing a light emitting diode (LED) display device including stacked micro-LED elements according to the present invention.

FIG. 2 illustrates (A) a cross-sectional view showing an operation of aligning a first micro-LED element on a first insulating layer without a groove according to the present invention, and (B) a cross-sectional view showing an operation of aligning a first micro-LED element on a first insulating layer with a groove.

FIG. 3 is a plan view of FIG. 2, (B).

FIG. 4 illustrates (A) a cross-sectional view showing an operation of forming a second insulating layer without a groove according to the present invention, and (B) a cross-sectional view showing an operation of forming a second insulating layer with a groove.

FIG. 5 is a plan view of FIG. 4, (B).

FIG. 6 illustrates (A) a cross-sectional view showing an operation of aligning a second micro-LED element on a second insulating layer without a groove according to the present invention, and (B) a cross-sectional view showing an operation of aligning a second micro-LED element on a second insulating layer with a groove.

FIG. 7 is a plan view of FIG. 6.

FIGS. 8 and 9 are cross-sectional views when viewed in a y-axis direction among x, y, and z-axis directions when two grooves according to the present invention are present.

FIG. 10 is a cross-sectional view when viewed in the y-axis direction among the x, y, and z-axis directions when three grooves according to the present invention are present.

FIG. 11 is a cross-sectional view when viewed in the y-axis direction among the x, y, and z-axis directions when four grooves according to the present invention are present.

FIG. 12 is a cross-sectional view when viewed in the y-axis direction among the x, y, and z-axis directions when a plurality of grooves according to the present invention are present.

FIG. 13 is a cross-sectional view for describing an operation of coupling both ends of a plurality of micro-LED elements according to the present invention to a first electrode layer and a second electrode layer in a first method.

FIG. 14 is a cross-sectional view for describing an operation of coupling both ends of the plurality of micro-LED elements according to the present invention to the first electrode layer and the second electrode layer in a second method.

FIG. 15 is a plan view of FIGS. 13 and 14.

FIG. 16 illustrates cross-sectional views (A) and (B) showing luminous efficiency in the case of a stacked micro-LED element assembly according to the present invention.

FIG. 17 illustrates (A) a cross-sectional view and (B) a plan view showing a structure in which a partition wall is disposed in the stacked micro-LED element assembly according to the present invention.

FIG. 18 is a cross-sectional view showing a structure in which a partition wall and a color conversion layer are disposed in the stacked micro-LED element assembly according to the present invention.

### DESCRIPTION OF REFERENCE NUMERALS

10: substrate
20a: first electrode layer
20b: second electrode layer
30: first insulating layer
32: first groove
40: second insulating layer
42: second groove
50: first connection electrode
60: second connection electrode
70: partition wall
80a, 80b, 80c: color conversion particles

### DETAILED DESCRIPTION

The above-described objects, features, and advantages will be described below in detail with reference to the accompanying drawings, and thus those skilled in the art to which the present invention pertains will be able to easily carry out the technical spirit of the present invention. In describing the present invention, when it is determined that a detailed description of the known technology related to the present invention may unnecessarily obscure the gist of the present invention, a detailed description thereof will be omitted. Hereinafter, exemplary embodiments according to the present invention will be described in detail with reference to the accompanying drawings. In the drawings, the same reference numerals are used to denote the same or similar components.

Hereinafter, the arrangement of an arbitrary component on an “upper portion (or lower portion)” of a component or “above (or under)” the component may not only mean that the arbitrary component is disposed in contact with an upper surface (or a lower surface) of the component, but also mean that other components may be interposed between the component and the arbitrary component disposed above (or under) the component.

In addition, when a certain component is described as being “connected,” “coupled,” or “joined” to another component, the components may be directly connected or joined, but it should be understood that other components may be “interposed” between the components, or the components may be “connected,” “coupled,” or “joined” through the third component.

Hereinafter, a light emitting diode (LED) display device including a stacked micro-LED element and a method of manufacturing the same according to some embodiments of the present invention will be described.

The present invention is directed to providing an LED display device and a method of manufacturing the same, which have better brightness and resolution by aligning a plurality of micro-LED elements so that a longitudinal direction of the micro-LED element is parallel to a plane (bottom surface) of a substrate and stacking the plurality of micro-LED elements in a direction perpendicular to the plane of the substrate to be spaced apart from each other to integrate a large number of micro-LED elements compared to an area.

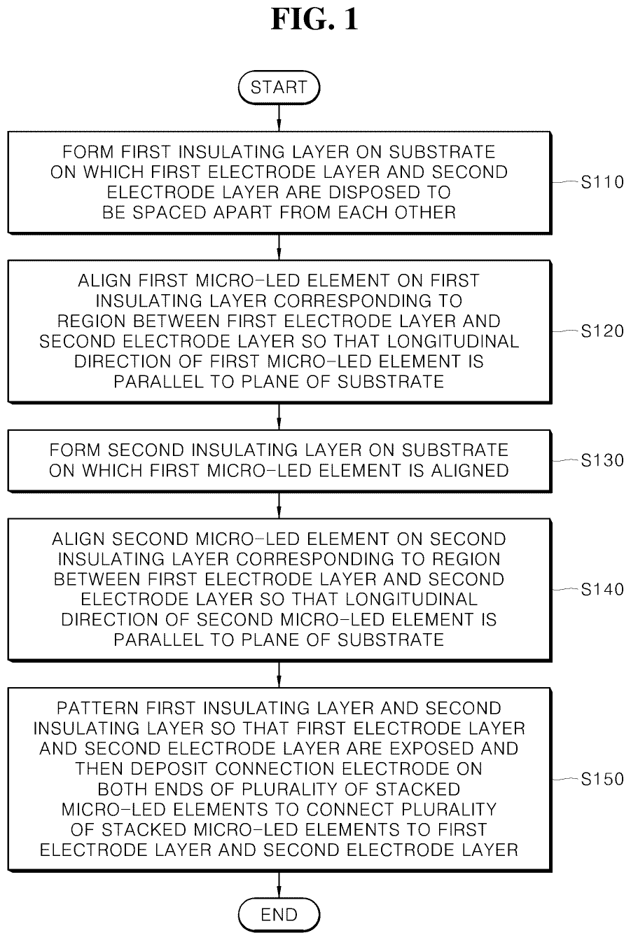

FIG. 1 is a flowchart showing a method of manufacturing an LED display device including stacked micro-LED elements according to the present invention.

Referring to FIG. 1, the method for manufacturing an LED display device according to the present invention may include forming a first insulating layer on a substrate on which a first electrode layer and a second electrode layer are disposed to be spaced apart from each other (S110), aligning a first micro-LED element on the first insulating layer corresponding to a region between the first electrode layer and the second electrode layer so that a longitudinal direction of the first micro-LED element is parallel to a plane of the substrate (S120), forming a second insulating layer on the substrate on which the first micro-LED element is aligned (S130), aligning a second micro-LED element on the second insulating layer corresponding to a region between the first electrode layer and the second electrode layer so that a longitudinal direction of the second micro-LED element is parallel to the plane of the substrate (S140), and patterning the first insulating layer and the second insulating layer so that the first electrode layer and the second electrode layer are exposed, and then depositing a connection electrode at both ends of the plurality of stacked micro-LED elements to connect the plurality of stacked micro-LED elements to the first electrode layer and the second electrode layer (S150).

A first insulating layer 30 may be formed on a substrate 10 on which a first electrode layer 20a and a second electrode layer 20b are disposed to be spaced apart from each other.

The substrate may be a rigid substrate formed of glass, a flexible substrate formed of a thin film made of plastic or a metal material, or an active matrix backplane. In addition, the substrate may be a transparent substrate, but is not limited thereto.

The substrate may have a transistor (not shown) disposed in each of a plurality of pixel regions defined by crossing data lines and gate lines. The LED display device may have a structure in which micro-LED element is disposed coplanarly with the transistor or in which the micro-LED element is disposed on the transistor.

In addition, the first electrode layer and the second electrode layer may have a structure in which they are disposed to be spaced apart from each other on the transistor.

Although the transistor is not shown in the drawings of the present invention, this is only one embodiment, and the present invention is not limited thereto.

In general, in a circuit of the display device, a micro-LED element needs to be connected to an electrode, and thus a number of metal wirings are required. Therefore, it is important to minimize this phenomenon because parasitic electric fields may be generated in undesirable places during an assembly process of micro-LED elements using electric fields.

To this end, it is preferable to form a metal layer that functions as an electric field shielding layer over the entire region to cover all elements of the circuit and functions as an alignment layer for the element.

When the metal layer is formed over the entire region of the substrate, the generation of parasitic electric fields can be minimized, and at the same time, elements thereunder can be protected from electric fields.

The metal layer may include at least one of Ag, Mg, Al, Pt, Pd, Au, Ni, Nd, Ir, Cr, and Ti, include a conductive oxide such as ITO, IZO, ZnO, or ITZO, and also include a conductive polymer such as PEDOT.

To arrange the first electrode layer 20a and the second electrode layer 20b to be spaced apart from each other on the substrate 10, the following process may be performed.

The first electrode layer and the second electrode layer spaced apart from each other may be formed by arranging the metal layer to entirely cover one surface of the substrate and then removing region A corresponding to a location where the micro-LED element is aligned from the metal layer. Here, region A may have a trench shape with a short width and a long length.

Photoresist may be applied on the metal layer, and region A may be removed from the metal layer using an etching mask and UV exposure.

The photoresist is a photosensitive liquid that is sensitive to light and contains an organic solvent and a polymer material. After spin-coating the photoresist, the organic solvent in the photoresist may be removed. Photoresist PR may form a pattern using light and is classified into negative PR and positive PR. The negative PR removes a part that does not receive light when the light is radiated because particles aggregate when receiving the light. The positive PR removes only a part that receives light when the light is radiated because polymer bonds break when receiving the light.

The thicknesses of the first electrode layer 20a and the second electrode layer 20b may range from 10 to 200 nm, preferably from 10 to 100 nm, but are not limited thereto.

A first insulating layer 30 may be formed on the substrate to cover both the first electrode layer 20a and the second electrode layer 20b.

When the first insulating layer is not present on the first electrode layer and the second electrode layer, a short may occur when the micro-LED element is arranged between the first electrode layer and the second electrode layer. In addition, even when the first insulating layer and the groove are not present, the micro-LED element may be arranged, but there is a problem that a high current flows at the moment of arrangement, causing the micro-LED element to be destroyed.

Therefore, it is preferable to form the first insulating layer on the first electrode layer and the second electrode layer.

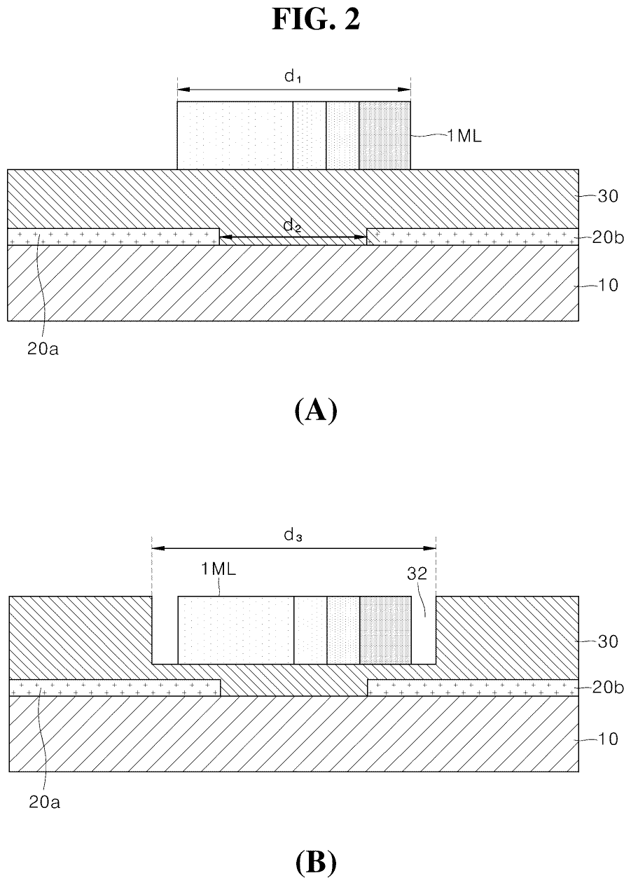

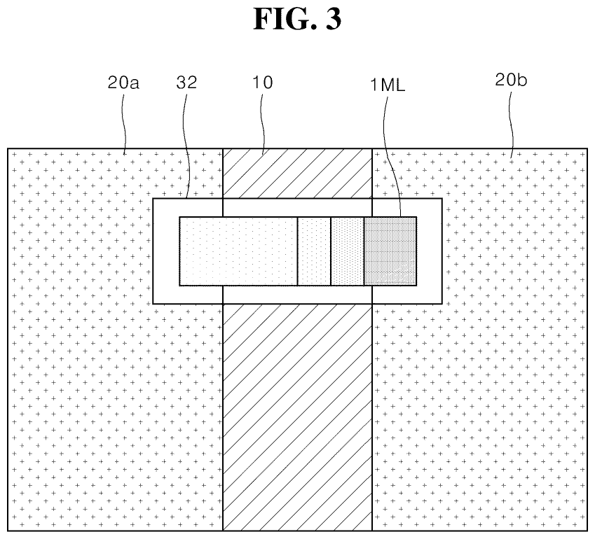

FIG. 2 illustrates (A) a cross-sectional view showing an operation of aligning a first micro-LED element on a first insulating layer without a groove according to the present invention, and (B) a cross-sectional view showing an operation of aligning a first micro-LED element on a first insulating layer with a groove, and FIG. 3 is a plan view of FIG. 2, (B).

As shown in FIGS. 2 and 3, a first micro-LED element 1ML may be aligned on the first insulating layer 30 corresponding to a region between the first electrode layer 20a and the second electrode layer 20b so that a longitudinal direction of the first micro-LED element 1ML is parallel to the plane of the substrate.

The first insulating layer 30 may have a planarized upper surface without a groove as in FIG. 2 (A) or have an upper surface with a groove as in FIG. 2, (B).

Specifically, forming the first insulating layer with a groove may include forming one or more first grooves 32 in the region between the first electrode layer 20a and the second electrode layer 20b of the first insulating layer 30, and aligning one first micro-LED element 1ML in one first groove 32 so that the longitudinal direction of the first micro-LED element 1ML is parallel to the plane of the substrate.

The first groove may be formed to pattern the region between the first electrode layer and the second electrode layer of the first insulating layer to a predetermined thickness to induce the generation of a strong electric field between the first electrode layer and the second electrode layer.

When the first insulating layer is patterned, it means that an insulating material of the first groove part is not completely removed but a lower portion thereof remains at a predetermined thickness and an upper portion thereof is removed.

For example, partial patterning may be performed by a method of applying and patterning an insulator such as a polymer-based organic material and/or one or more inorganic materials such as SiO₂, Si₃N₄, SiNₓ, Al₂O₃, HfO₂, Y₂O₃, and TiO₂ so that the insulating material of the groove part is patterned more. The patterning may be performed using exposure and development or performed using dry etching or wet etching.

The method of applying the insulator may be performed by plasma enhanced chemical vapor deposition (PECVD), physical vapor deposition (PVD), chemical vapor deposition (CVD), e-beam deposition, atomic layer deposition (ALD), or sputtering deposition, but is not limited thereto.

The groove including a first groove 32, a second groove 42, etc. is a space in which micro-LED elements are aligned and may be formed at regular intervals in the region between the first electrode layer and the second electrode layer.

In this case, the groove preferably overlaps the region between the first electrode layer and the second electrode layer.

When an electrical signal is applied to the first electrode layer and the second electrode layer, a relatively high electric field is generated in the groove to cause a strong attractive force to be generated in the corresponding part, making it easy to align the micro-LED element in the groove. Electric fields with different intensities (magnitudes) are generated near the electrode layer including the groove to attract or repulse the micro-LED element. This is because the groove region is closer to the first electrode layer and the second electrode layer than a non-groove region is to locally increase the strength of the electric field in the groove region.

The first electrode layer and the second electrode layer that are located in the groove region may be disposed to protrude toward each other. With this structure, it is more advantageous in accurately aligning the micro-LED element by more intensively generating the electric field generated by applying a voltage in the protruding region.

Regarding a width, as shown in FIG. 2, a length d₁ of the micro-LED element is preferably larger than a width d₂ of the region between the first electrode layer and the second electrode layer. A width d₃ of the first groove is preferably larger than the length d₁ of the micro-LED element and larger than the width d₂ of the region between the first electrode layer and the second electrode layer. Here, the width d₃ of the first groove may be the same as or similar to a width of the second groove.

The thickness of the first insulating layer before patterning may be formed to a thickness of about 100 to 600 nm, preferably, 100 to 400 nm, but is not limited thereto. In addition, the thickness of the first insulating layer between the groove and the first electrode layer and the second electrode layer may range from about 10 to 400 nm, preferably, from 10 to 200 nm, and more preferably, from 10 to 100 nm or from 10 to 50 nm, but is not limited thereto.

The aligning of the first micro-LED element may include aligning one first micro-LED element 1ML in one first groove 32 by supplying a fluid including the first micro-LED elements 1ML on the substrate 10 and applying an electrical signal to the first electrode layer 20a and the second electrode layer 20b to generate an electric field.

Specifically, when the electrical signal is applied by an electrical signal supplier (not shown), the fluid may be a liquid having a lower dielectric constant than the first micro-LED element. The fluid may be a liquid containing one or more of isopropyl alcohol, acetone, toluene, ethanol, methanol, and distilled water.

While the fluid including the plurality of first micro-LED elements is supplied on the substrate, the electrical signal supplier applies a voltage to the first electrode layer and the second electrode layer to generate an electric field between the first electrode layer and the second electrode layer. When the electric field is generated, one of the plurality of micro-LED elements included in the fluid may be arranged inside the first groove so that the longitudinal direction of the first micro-LED element is parallel to the plane of the substrate by the attraction of the electric field.

When the first electrode layer is a positive electrode and the second electrode layer is a negative electrode, one end of the first micro-LED element with a negative charge may be located toward the first electrode layer in the first groove. In addition, the other end of the first micro-LED element with a positive charge may be located toward the second electrode layer in the first groove.

The first electrode layer and the second electrode layer may function to generate an electric field and at the same time, function as an electric field shielding layer for other circuits, etc. under the first electrode layer and the second electrode layer.

The electrical signal supplier may supply a DC signal, an AC signal, or a pulsed DC signal to the first electrode layer and the second electrode layer. Preferably, the electrical signal supplier may supply the pulsed DC signal to the first electrode layer and the second electrode layer so that the arrangement direction of the micro-LED elements is constant in each groove.

Here, the pulsed DC signal is a periodic electrical signal whose value changes but polarity is kept constant. The electrical signal supplier may generate the pulsed DC signal by adding a bias DC signal to the AC signal.

In the present invention, the first micro-LED element 1ML, a second micro-LED element 2ML, . . . , an n^{th} micro-LED element nML are an ultra-small light-emitting material whose longest side has a length of about 100 μm or less. These micro-LED elements are organic or/and inorganic materials dispersed in a fluid and have various sizes of one-dimensional (1D), two-dimensional (2D), and three-dimensional (3D) shapes.

The micro-LED element may have a nanowire shape having a length, a flat and flat disk shape, or a cubic shape having an aspect ratio of 1 to 2.

Preferably, the micro-LED element may be an element that has a nanowire shape with a high aspect ratio and has a length of 1 to 100 μm, preferably, a length of 1 to 80 μm.

The nanowire-shaped micro-LED element may have an aspect ratio of about 1 to 10, preferably, 1 to 5. In addition, the nanowire-shaped micro-LED element may have a cross-sectional diameter of about 10 to 10,000 nm, preferably, 10 to 1,000 nm.

Since micro-LED elements with a high aspect ratio have a large surface area, the micro-LED elements have advantages of excellent energy transfer and performance and high transparency.

The micro-LED element according to the present invention may have the same configuration as commonly used LEDs and may include an n-type semiconductor layer, a p-type semiconductor layer, and an active layer interposed between the n-type semiconductor layer and the p-type semiconductor layer.

As shown in FIGS. 2 to 9 and 13 to 18 of the present invention, the micro-LED element may further include a transparent electrode for current distribution disposed on side surfaces of the p-type semiconductor layer having relatively high resistance, but is not limited thereto. Here, the transparent electrode may include one or more of a metal such as Al, Cu, Cr, or Ni and/or a transparent conductive oxide (TCO) material such as indium tin oxide (ITO) or fluorine-doped tin oxide (FTO).

Other than this, detailed descriptions of the micro-LED device will be omitted.

In the present invention, the plurality of micro-LED elements are stacked in a direction perpendicular to the plane of the substrate to integrate a large number of micro-LED elements compared to an area, thereby achieving high brightness and high resolution.

To perpendicularly stack the plurality of micro-LED elements, the forming of the insulating layer and then aligning the micro-LED element may be repeatedly performed, and specifically, the following operations may be performed.

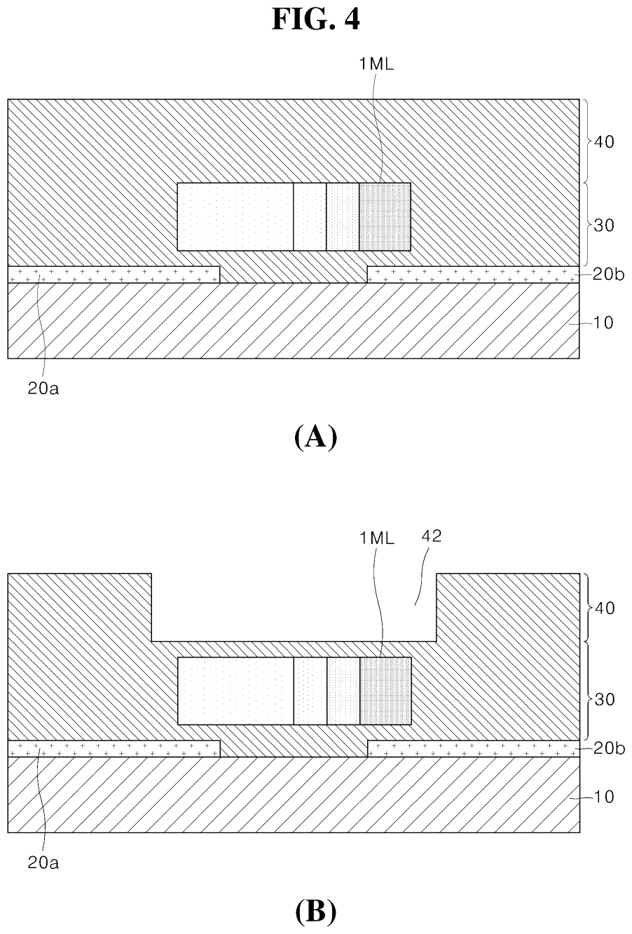

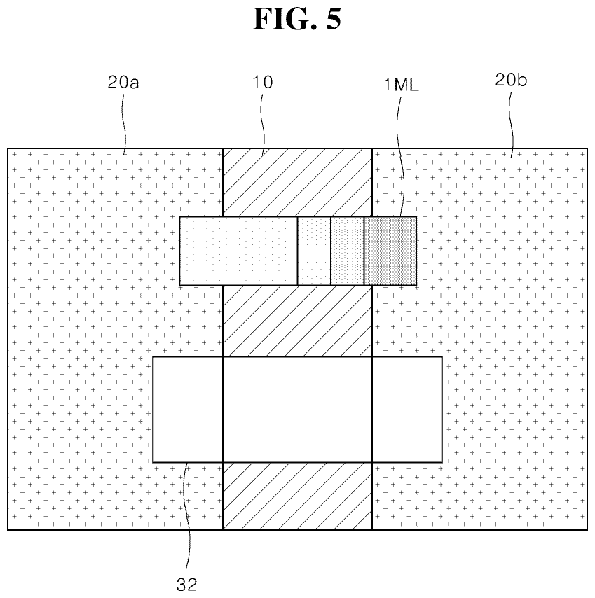

FIG. 4 illustrates (A) a cross-sectional view showing an operation of forming a second insulating layer without a groove according to the present invention, and (b) a cross-sectional view showing an operation of forming a second insulating layer with a groove, and FIG. 5 is a plan view of FIG. 4, (B).

As shown in FIGS. 4 and 5, a second insulating layer 40 may be disposed over the entire one surface to cover the first insulating layer 30 and the first micro-LED element 1ML to planarize the first insulating layer.

In the drawings of the present invention, the thickness of the second insulating layer 40 is shown as being smaller than the thickness of the first insulating layer 30, but this is only one embodiment, and the present invention is not limited thereto.

The forming of the second insulating layer may be the same as or similar to the forming of the first insulating layer. The second insulating layer 40 may have a planarized upper surface without a groove as in FIG. 4, (A) or have an upper surface with a groove as in FIG. 4, (B).

Specifically, forming the second insulating layer with a groove may include forming one or more second grooves 42 in the region between the first electrode layer 20a and the second electrode layer 20b of the second insulating layer 40, and aligning one second micro-LED element 2ML in one second groove 42 so that the longitudinal direction of the second micro-LED element 2ML is parallel to the plane of the substrate.

According to various embodiments, the second groove 42 may be formed at various locations in the region between the first electrode layer and the second electrode layer. This means that the second micro-LED element aligned to the second groove may be disposed at various locations in the region between the first electrode layer and the second electrode layer.

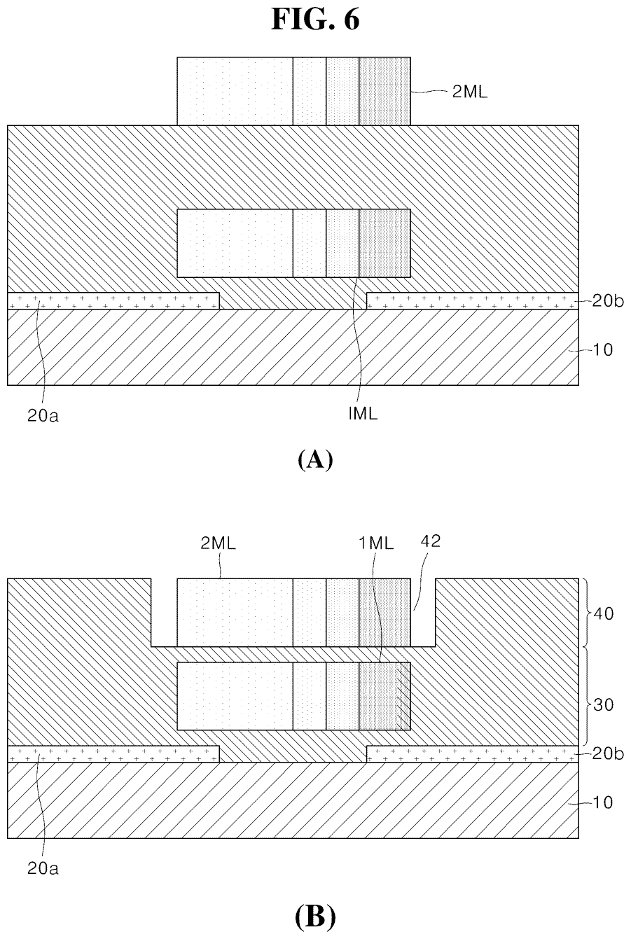

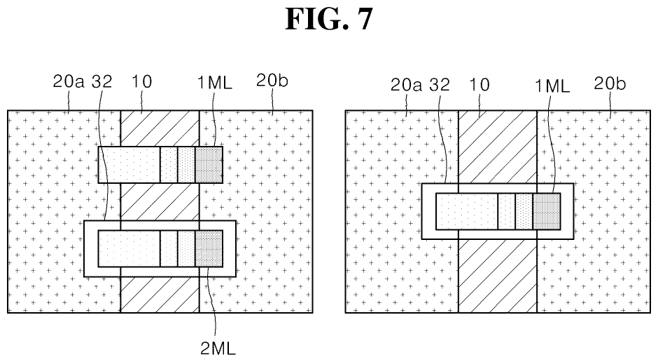

FIG. 6 illustrates (A) a cross-sectional view showing an operation of aligning a second micro-LED element on a second insulating layer without a groove according to the present invention, and (B) a cross-sectional view showing an operation of aligning a second micro-LED element on a second insulating layer with a groove, and FIG. 7 is a plan view of FIG. 6.

As shown in FIGS. 6 and 7, one second micro-LED element 2ML may be aligned in one second groove 42 so that the longitudinal direction of the second micro-LED element 2ML is parallel to the plane of the substrate.

The aligning of the second micro-LED element may include aligning one second micro-LED element in one second groove by supplying a fluid including the second micro-LED elements on the substrate and applying an electrical signal to the first electrode layer and the second electrode layer to generate an electric field.

In this case, the longitudinal direction of the second micro-LED element aligned to the second groove may coincide with the longitudinal direction of the micro LED element aligned to the other groove. At least one of the micro-LED elements may be aligned in a diagonal direction, but is not limited thereto.

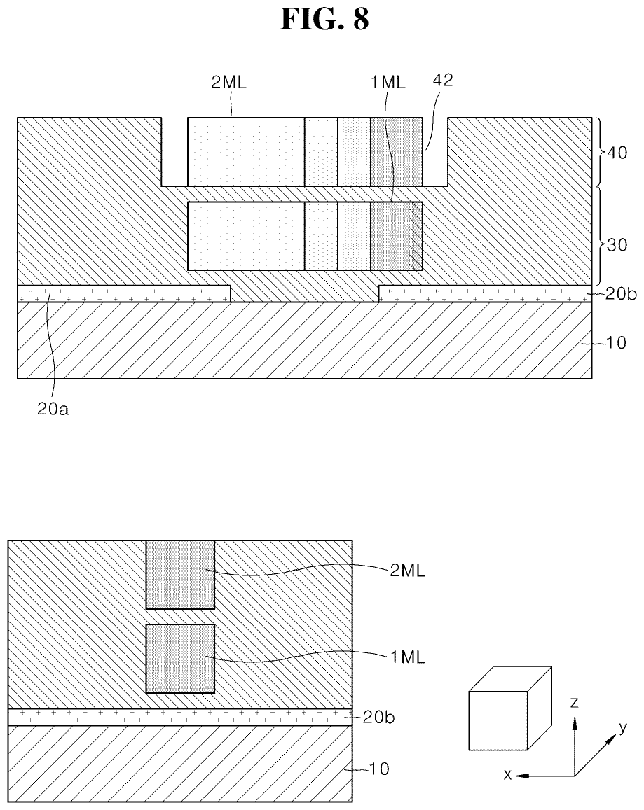

FIGS. 8 to 12 are cross-sectional views showing various arrangement structures of the stacked micro-LED element according to the present invention.

The first drawing of FIG. 8 is a structure when viewed in an x-axis direction, and the second drawing thereof is a structure when viewed in a y-axis direction.

As shown in FIG. 8, when two grooves are present, when viewed in the y-axis direction among x, y, and z-axis directions, a second groove may be formed on the first groove so that the first groove overlaps the second groove. In this case, one first micro-LED element 1ML and one second micro-LED element 2ML may have the same location in a horizontal direction and have different locations in a vertical direction.

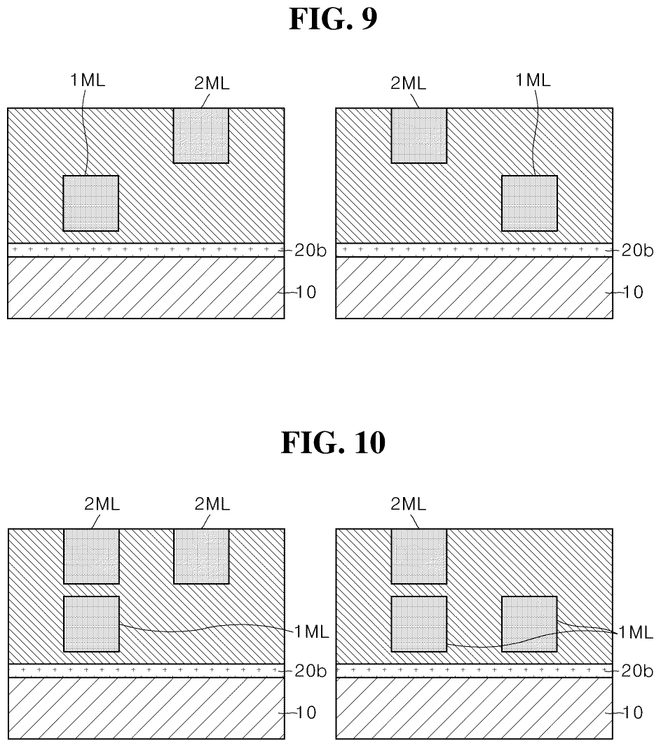

As shown in FIG. 9, when two grooves are present, when viewed in the y-axis direction among the x, y, and z-axis directions, a second groove may be formed in a diagonal direction of the first groove so that the first groove does not overlap the second groove. In this case, one first micro-LED element 1ML and one second micro-LED element 2ML may have different locations in the horizontal direction and also have different locations in the vertical direction.

As shown in FIG. 10, when three grooves are present, when viewed in the y-axis direction among the x, y, and z-axis directions, one first groove and two second grooves may be formed, or two first grooves and one second groove may be formed.

In this case, one first micro-LED element 1ML and one second micro-LED element 2ML may be aligned to overlap in the vertical direction, and at the same time, the other second micro-LED element 2ML may be formed in a diagonal direction of the one first micro-LED element 1ML. Alternatively, in the state in which the first micro-LED element 1ML and the second micro-LED element 2ML are aligned to overlap each other, the other first micro-LED element 1ML may be formed in a diagonal direction of the one second micro-LED element 2ML. This case means that the three micro-LED elements have different locations in the horizontal direction and also have different locations in the vertical direction.

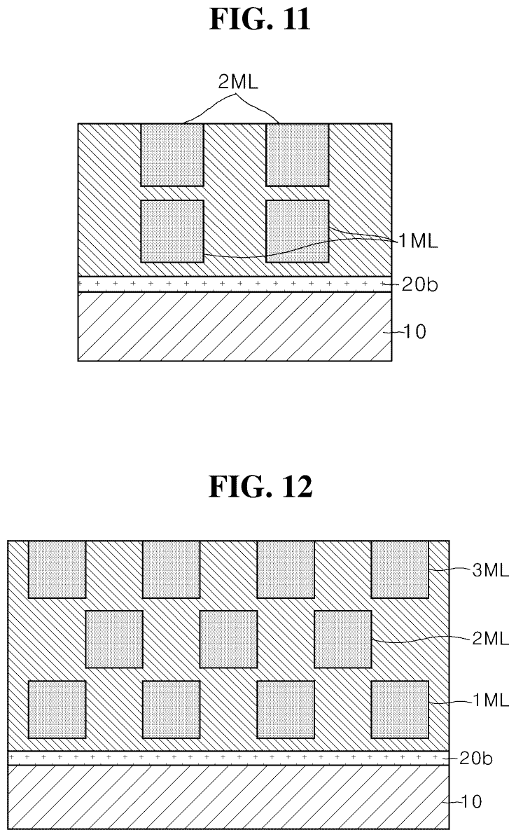

As shown in FIG. 11, when four grooves are present, when viewed in the y-axis direction, the plurality of first grooves disposed to be spaced apart from each other may be formed in the horizontal direction of the substrate, and the second groove may also be formed upward from the first groove. In this case, the first micro-LED element 1ML and the second micro-LED element 2ML may have different locations in the horizontal direction and also have different locations in the vertical direction.

As shown in FIG. 12, when a plurality of grooves are present, when viewed in the y-axis direction, a plurality of first grooves may be formed in the horizontal direction of the substrate, and different grooves may also be formed upward and diagonally from the first groove. This means that the plurality of micro-LED elements may have different locations in the horizontal direction and the vertical direction.

In addition, assuming that a first row is located at the lowermost portion, a second row is located above the first row, and a third row is located above the second row, micro-LED elements in odd rows may overlap each other, and micro-LED elements in even rows may overlap each other. In addition, the micro-LED elements in the even rows may not overlap the micro-LED elements in the odd rows.

In this way, two or more grooves are preferably formed in the region between the first electrode layer and the second electrode layer and at the same time, formed in at least one of the overlapping locations and the diagonal direction.

Depending on the specifications and size of the LED display device, the number of grooves to be formed in the horizontal direction and the number of grooves to be formed in the vertical direction may be adjusted.

In the present invention, to manufacture the LED display device including the stacked micro-LED element, forming an insulating layer and aligning the micro-LED element on the insulating layer corresponding to the region between the first electrode layer and the second electrode layer so that the longitudinal direction of the micro-LED element is parallel to the plane of the substrate may be performed one or more times between the aligning of the second micro-LED element (S160) and the connecting the plurality of stacked micro-LED elements to the first electrode layer and the second electrode layer (S170).

As described above, the forming of the insulating layer may further include forming a groove in the insulating layer.

Lastly, after the first insulating layer 30 and the second insulating layer 40 are patterned so that the first electrode layer 20a and the second electrode layer 20b are exposed, a first connection electrode 50 may be deposited at one ends of the plurality of stacked micro-LED elements, and a second connection electrode 60 may be deposited at the other ends. In addition, the LED display device may be manufactured by connecting the plurality of stacked micro-LED elements to the first electrode layer and the second electrode layer.

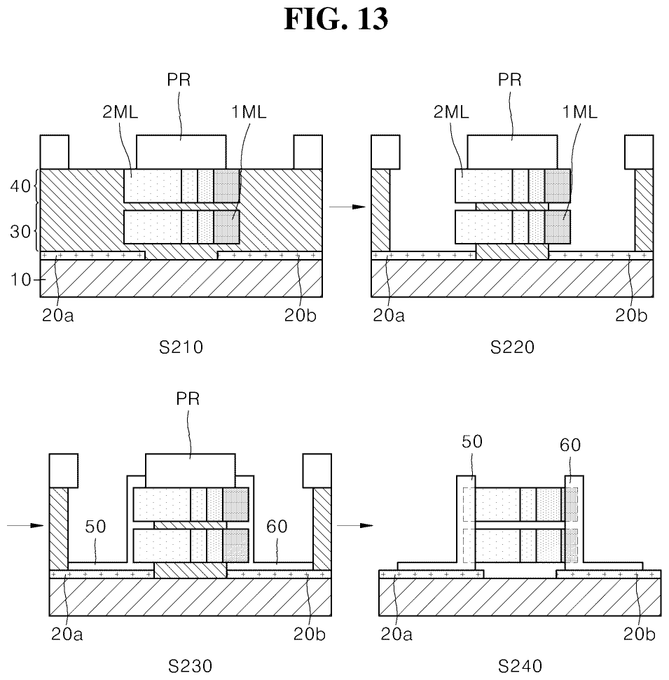

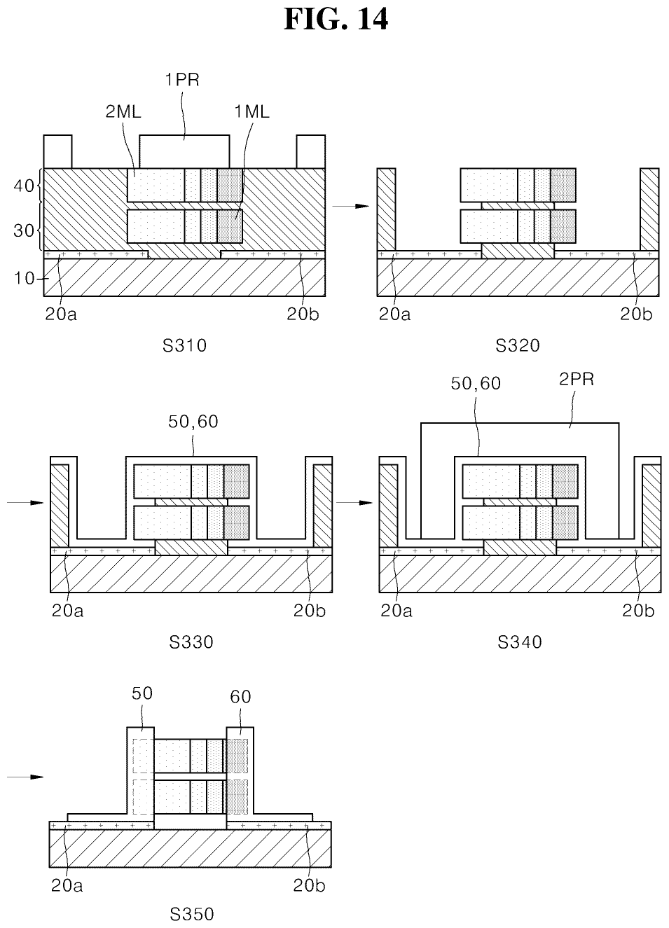

This operation may be performed in one of two ways, in which a first way is shown in FIG. 13, and a second way is shown in FIG. 14.

As shown in S210 of FIG. 13, after photoresist PR is applied on a substrate on which the plurality of stacked micro-LED elements 1ML and 2ML are disposed, a portion of the photoresist corresponding to both ends of the plurality of micro-LED elements may be removed.

After the photoresist is entirely applied to the first insulating layer 30, the second insulating layer 40, and the plurality of micro-LED elements, the photoresist may be patterned by removing the portion corresponding to both ends of the plurality of micro-LED elements, that is, regions of the photoresist above the first electrode layer 20a and the second electrode layer 20b, using an etching mask and UV radiation.

As shown in S220 of FIG. 13, the first insulating layer and the second insulating layer may be patterned by removing portions of the first insulating layer 30 and the second insulating layer 40 corresponding to both ends of the plurality of micro-LED elements so that the first electrode layer 20a and the second electrode layer 20b are exposed. The patterning may be performed using an etching mask and UV radiation, and the removed portions are spaces in which the first connection electrode 50 and the second connection electrode 60 are formed.

As shown in S230 of FIG. 13, the first connection electrode 50 may be deposited to extend from one ends of the plurality of stacked micro-LED elements to the first electrode layer. In addition, the second connection electrode 60 may be deposited to extend from the other ends of the plurality of stacked micro-LED elements to the second electrode layer. Therefore, the one ends of the plurality of micro-LED elements may be connected to the first electrode layer 20a and the other ends may be connected to the second electrode layer 20b by the deposited connection electrodes 50 and 60.

The first connection electrode 50 may connect the one ends of the plurality of stacked micro-LED elements to the first electrode layer 20a. The second connection electrode may connect the other ends of the plurality of stacked micro-LED elements to the second electrode layer 20b. Since a conductive material may be deposited on the plurality of micro-LED elements arranged in the vertical direction and/or the horizontal direction to form the first connection electrode 50 at the one ends thereof and the second connection electrode 60 at the other ends at once, the stacked micro-LED elements can be stably arranged at their respective locations, and it is possible to maximize luminous efficiency using a simple process.

When an electrode is formed on each layer on which the micro-LED element is disposed such as forming the connection electrode at both sides of the first micro-LED element after arranging the first micro-LED element and forming the connection electrode at both sides of the second micro-LED element after arranging the second micro-LED element on the first micro-LED element, the electrode forming process needs to be performed many times, and thus there is a disadvantage that the manufacturing cost is very increased. In addition, since the electrode forming process needs to be performed on each layer, there is a problem that the contact resistance of the connection electrode in each layer is different.

Therefore, as in the present invention, when the connection electrodes are formed at once in order to connect the plurality of stacked micro-LED elements to the first electrode layer and the second electrode layer, there is an advantage that the connection electrodes having a regular shape as much as possible may be formed using a simple process.

As shown in S240 of FIG. 13, the LED display device may be manufactured by removing all of the first insulating layer and the second insulating layer that are present between the micro-LED elements, the first insulating layer and the second insulating layer that are present between the first electrode layer and the second electrode layer, and the photoresist present on the micro-LED elements.

The insulating layer and the photoresist may be removed using a lift-off method, but the present invention is not limited thereto.

As shown in S310 of FIG. 14, after applying a first photoresist 1PR on the substrate 10 on which the plurality of stacked micro-LED elements are disposed, portions of the first photoresist corresponding to both ends of the plurality of micro-LED elements may be removed.

As shown in S320 of FIG. 14, after removing the portions of the first insulating layer 30 and the second insulating layer 40 corresponding to both ends of the plurality of micro-LED elements so that the first electrode layer 20a and the second electrode layer 20b are exposed, the first photoresist 1PR may be removed.

As shown in S330 of FIG. 14, the connection electrodes 50 and 60 may be deposited on the entire surface of the substrate 10 on which the plurality of micro-LED elements are disposed to connect one ends of the plurality of micro-LED elements to the first electrode layer 20a and connect the other ends of the plurality of micro-LED elements to the second electrode layer 20b. The connection electrode corresponds to the first connection electrode and the second connection electrode, and the first connection electrode and the second connection electrode may be formed by separating or patterning the connection electrode.

As shown in S340 of FIG. 14, a second photoresist 2PR is applied on the substrate on which the connection electrodes 50 and 60 are deposited, and the second photoresist 2PR may be applied to upper portions and side surfaces of the plurality of micro-LED elements. Here, the upper portions and side surfaces are outer perimetric surfaces of the plurality of stacked micro-LED elements and are portions that surround the stacked elements.

Subsequently, as shown in S350 of FIG. 14, after removing the first insulating layer, the second insulating layer, and the connection electrode from portions where the second photoresist 2PR is not applied, the remaining second photoresist, the first insulating layer, and the second insulating layer may be removed.

In this way, the second method may be a process of depositing the connection electrode to cover the entire upper surface of the substrate in the process of forming the connection electrode and then removing only the unnecessary portion.

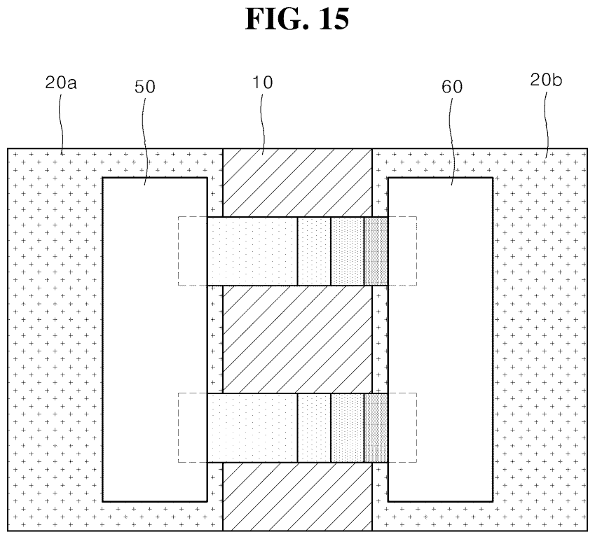

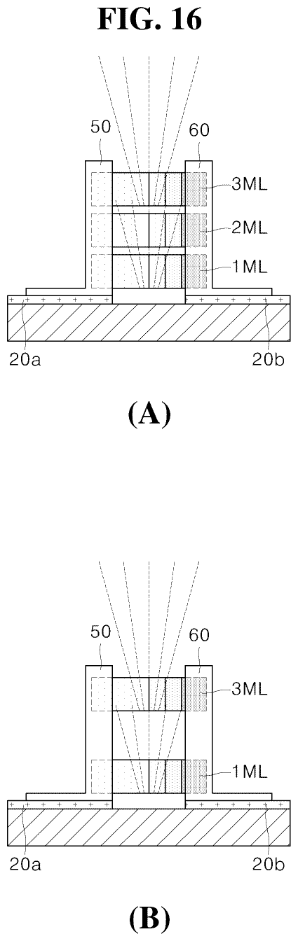

FIG. 15 is a plan view of FIGS. 13 and 14. As shown in FIG. 15, one ends of the plurality of stacked micro-LED elements overlap the first electrode layer 20a and the first connection electrode 50, and the other ends overlap the second electrode layer 20b and the second connection electrode 60.

In the present invention, the method of forming the first electrode layer and the second electrode layer, and the first connection electrode and the second connection electrode may be performed by PECVD, PVD, CVD, e-beam deposition, ALD, sputtering deposition, or plating, but is not limited thereto.

Each of the first connection electrode and the second connection electrode may include one or more of Ag, Mg, Al, Pt, Pd, Au, Ni, Nd, Ir, Cr, and Ti, include a conductive oxide such as ITO, IZO, ZnO, or ITZO, and also include a conductive polymer such as PEDOT, but is not limited thereto.

FIG. 16 illustrates cross-sectional views (A) and (B) showing luminous efficiency in the case of a stacked micro-LED element assembly according to the present invention.

As shown in FIG. 16, in the present invention, by manufacturing the LED display device by stacking the micro-LED elements in a direction perpendicular to the plane of the substrate in the state in which the longitudinal direction of the plurality of micro-LED elements is parallel to the plane of the substrate to integrate a larger number of LED elements in a relatively small area, it is possible to further increase brightness.

In addition, even when an element that does not emit light is present among the stacked micro-LED elements, since the micro-LED elements located at the top, bottom, or in a diagonal direction emit light, it is possible to maintain or improve the luminous characteristics of the pixel.

In addition, when the micro-LED elements are stacked, brightness can be increased without consuming more area of the pixel of the LED display device, and thus a large pixel area can be used.

When the micro-LED elements that are stacked to be spaced apart from each other between the first electrode layer and the second electrode layer are coupled, one light source, that is, one pixel, may be formed. When a driving current flows in one pixel, the micro-LED elements connected between the first electrode layer and the second electrode layer emit light.

In this case, to minimize the interference phenomenon between pixels and enhance the directivity of light in the pixel, a partition wall 70 may be formed at the edge of the pixel.

Specifically, in the present invention, after the connecting of both ends of the plurality of micro-LED elements to the first electrode layer and the second electrode layer, arranging a partition wall including a metal layer on the side surfaces of the stacked micro-LED elements may be further included.

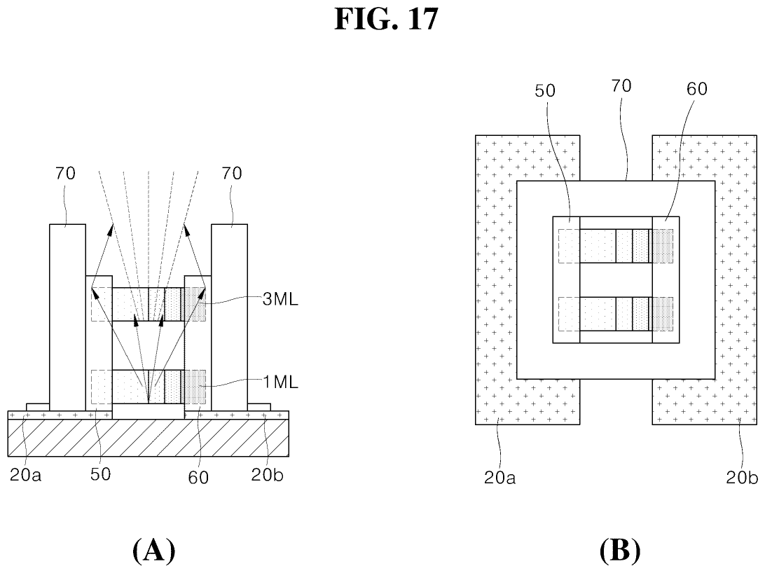

As shown in FIG. 17, the partition wall 70 may be disposed on the side surfaces of the plurality of stacked micro-LED elements and the side surfaces of the first connection electrode and the second connection electrode. Two or more partition walls may be present to surround the first connection electrode, the second connection electrode, and the micro-LED elements. Preferably, four partition walls each disposed on a different surface may be present, or one partition wall continuously disposed on four different surfaces to form a quadrangular shape may be present.

The partition wall may be formed from a location of the micro-LED element aligned at the lowermost portion to a location of the micro-LED element aligned at the uppermost portion. A height of the partition wall may be equal to or higher than a height of the micro-LED element aligned at the uppermost portion. When the height of the partition wall is equal to or higher than the heights of the plurality of stacked micro-LED elements, it is possible to further increase the light efficiency of the pixel by guiding the light emitted from the plurality of stacked micro-LED elements in a desired direction.

The partition wall may have a cross-sectional shape that is inclined outward as it goes downward, or a vertical cross-sectional shape, but is not limited thereto.

The partition wall may be made of an insulating material including an inorganic material or/and an organic material and formed through a mask process, but is not limited thereto.

The partition wall may include a reflective metal layer including one or more of Ag, Mg, Al, Pt, Pd, Au, Ni, Nd, Ir, Cr, and Ti therein. Preferably, the reflective metal layer may include one or more of Al, Au, Ni, Ti, Ag, and Mg.

By including the reflective metal layer on an inner surface of the partition wall, the light emitted from the micro-LED element is reflected by the reflective metal layer of the partition wall, and the reflected light further progresses forward (upward from the substrate) from the LED display device without loss.

In the present invention, after the arranging of the partition wall, arranging a color conversion layer in which color conversion particles are dispersed on at least one of upper portions, lower portions, and side surfaces of the plurality of stacked micro-LED elements and a gap between the plurality of stacked micro-LED elements may be further included.

A plurality of pixels may each display a different color. In some cases, adjacent pixels may display the same color.

For example, a first pixel may emit light of a first color, a second pixel may emit light of a second color, and a third pixel may emit light of a third color. Each pixel may include micro-LED elements that emit light of the same color and a color conversion layer that converts the light emitted from the micro-LED elements into light of different colors. By including the color conversion layer, each pixel may display a different color, and an LED display device having pixels of full RGB colors may be manufactured.

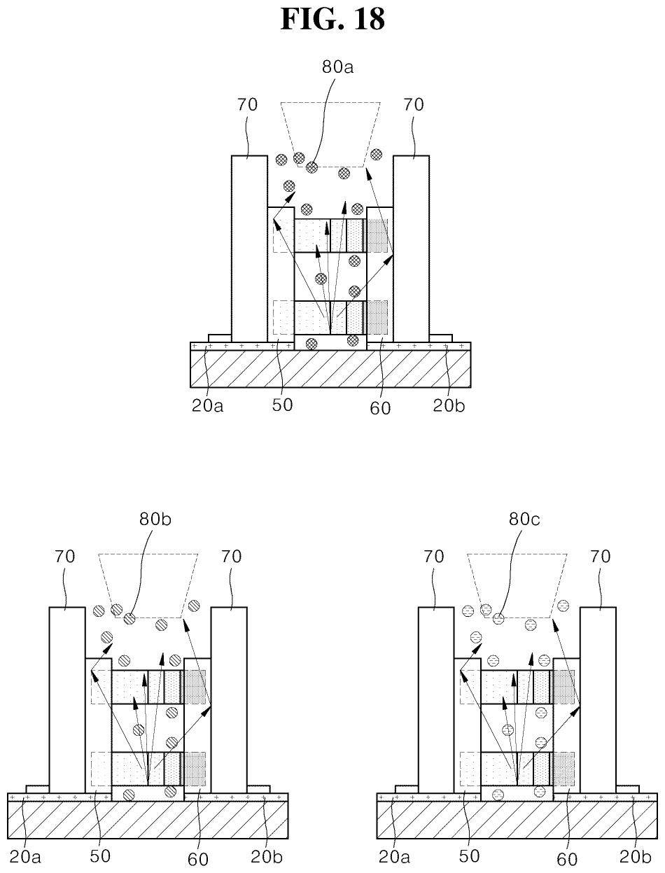

As shown in FIG. 18, the color conversion layer may include at least one color conversion particle. Color conversion particles 80a, 80b, and 80c may be disposed adjacent to at least one of upper portions, lower portions, and side surfaces of the plurality of stacked micro-LED elements and a gap between the plurality of stacked micro-LED elements and may also be disposed adjacent to the first electrode layer and the second electrode layer.

However, since the first connection electrode and the second connection electrode are present at both ends, that is, the side surfaces, of the plurality of stacked micro-LED elements, the color conversion layer may not be physically in direct contact with the plurality of stacked micro-LED elements.

The color conversion particles 80a, 80b, and 80c may convert light of any wavelength band emitted from the micro-LED element and light of any wavelength band reflected from the partition wall into light of a different wavelength band. For example, when the micro-LED element emits blue light to be incident on the color conversion layer, the color conversion particles of the color conversion layer may convert the blue light into red or green light.

Therefore, even when the micro-LED element emits light of the same color, the light emitted from the color conversion layer may be converted into light of various colors. The light converted in the color conversion layer may be displayed on an LED display device having each pixel.

The color conversion particles may include a quantum dot material. In this case, when first light having any wavelength band is incident on the color conversion particle, electrons in a valence band (VB) of the quantum dot material are excited to a level of a conduction band (CB). In addition, when the excited electrons are transferred back to the valence band, second light having the converted wavelength band may be emitted.

The quantum dot material may have a spherical core-shell structure. The core may be a semiconductor crystal material such as a silicon (Si)-based nanocrystal, a II-VI group compound nanocrystal, or a III-V group compound nanocrystal, but is not limited thereto.

In addition to the quantum dot material, the color conversion particle may include a material that may convert light of a specific wavelength band, which is incident on a fluorescent material, a plate-shaped material, a rod-shaped material, a perovskite material, etc., into light of a different wavelength band, but is not limited thereto.

In this way, the color conversion particles are dispersed adjacent to the micro-LED element, and most of the light emitted from the micro-LED elements may be incident on the color conversion particle, thereby implementing the LED display device having the pixels of full RGB colors.

The color conversion layer including the color conversion particles may be formed by selecting one of various processes such as an inkjet injection method and a photoresist method, or coupled to the micro-LED element in a manner in which the color conversion layer is attached to the micro-LED element by an adhesive, but is not limited thereto.

The LED display device according to the present invention may include a substrate, a first electrode layer and a second electrode layer, stacked micro-LED elements, and a first connection electrode and a second connection electrode that are coupled to both ends of the stacked micro-LED elements stacked to be spaced apart from each other.

Again, as shown in FIG. 16, the LED display device may include the first electrode layer 20a and the second electrode layer 20b that are disposed to be spaced apart from each other on the substrate 10, the micro-LED element ML stacked to be spaced apart from each other in the longitudinal direction to be parallel to the plane of the substrate on the first electrode layer and the second electrode layer and having a nanowire shape, and the first connection electrode 50 extending from one ends of the plurality of micro-LED elements stacked to be spaced apart from each other to the first electrode layer and connected to the first electrode layer, and the second connection layer 60 extending from the other ends of the plurality of micro-LED elements stacked to be spaced apart from each other to the second electrode layer and connected to the second electrode layer.

In the present invention, since the micro-LED elements have a structure in which the micro-LED elements are stacked to be spaced apart from each other in a direction perpendicular to the substrate in a state in which the longest side of the micro-LED element is parallel to the plane of the substrate to integrate a large number of micro-LED elements in a relatively small area, it is possible to further increase luminous efficiency.

In particular, the micro-LED elements stacked to be spaced apart from each other are located in the direction perpendicular to the substrate, but one micro-LED element and the other micro-LED element may also be located in a diagonal direction. Therefore, even when a micro-LED element that does not emit light occurs in a pixel, since the micro-LED element located on at least one of the upper and lower portions emits light.

In addition, the LED display device of the present invention may have one ends of the micro-LED elements stacked to be spaced apart from each other electrically connected to the first electrode layer through the first connection electrode and the other ends electrically connected to the second electrode layer through the second connection electrode. That is, since the micro-LED elements stacked to be spaced apart from each other are electrically connected to the first electrode layer and the second electrode layer through the first connection electrode and the second connection electrode, the stacked micro-LED elements emit light simultaneously, thereby further increasing brightness.

In addition, as shown in FIG. 17, the LED display device further include a partition wall including a metal layer disposed on the side surfaces of the micro-LED elements stacked to be spaced apart from each other, thereby minimizing the interference phenomenon between pixels and enhancing the directivity of light.

In addition, as shown in FIG. 18, the LED display device may further include a color conversion layer in which color conversion particles are dispersed on at least one of upper portions, lower portions, and side surfaces of the micro-LED elements stacked to be spaced apart from each other and a gap between the micro-LED elements to display full RGB colors.

Although not shown in the drawings of the present invention, the substrate may include a transistor disposed in each of a plurality of pixel regions defined by crossing data lines and gate lines.

Each pixel region may display an image and include a pixel circuit part and a display element layer.

The pixel circuit part may include at least one transistor and a driving voltage line DVL. The display element layer may include a first electrode layer electrically connected to the pixel circuit part, a second electrode layer electrically spaced from the first electrode layer, and stacked micro-LED elements coupled to the first electrode layer and the second electrode layer.

The first electrode layer may be connected to a source electrode or drain electrode of a transistor disposed in the pixel circuit part. The second electrode layer may be connected to a power supply voltage line VDD or a base voltage line Vss. The second electrode layer may be connected to the driving voltage line DVL through a contact electrode, but is not limited thereto.

In this way, in the LED display device of the present invention, one pixel may include transistors DT and ST formed on the substrate, one capacitor, and stacked micro-LED elements.

The transistor of the pixel circuit part is the driving transistor DT. In the transistor, each of the first electrode and the second electrode may be one of the source electrode and the drain electrode.

The present invention will be described assuming that the first electrode is the source electrode and the second electrode is the drain electrode.

A gate electrode of the switching transistor ST may be connected to a gate line GL, and a source electrode of the switching transistor ST may be connected to a data line DL. A drain electrode of the switching transistor ST may be connected to the gate electrode of the driving transistor DT and a first terminal of a storage capacitor Cst.

The switching transistor ST connects the data line DL to the gate electrode of the driving transistor DT in response to a signal supplied through the gate line GL.

A gate electrode of the driving transistor DT may be connected to the drain electrode of the switching transistor ST through a via Via3. A source electrode of the driving transistor DT may be connected to a ground GND through a via Via1.

A drain electrode of the driving transistor DT may be connected to the micro-LED element. A gate insulating film is formed on the gate electrode of the driving transistor DT, and the gate insulating film is formed in the form of surrounding the gate electrode. An active layer is formed on the gate insulating film, and the active layer is formed in a portion of the gate insulating film.

The driving transistor DT causes a current corresponding to a voltage charged in the storage capacitor Cst to flow from the power supply voltage line VDD to the ground GND through the micro-LED element.

The storage capacitor Cst may be connected between the gate electrode of the driving transistor DT and the ground GND. In addition, the micro-LED element may be connected between the drain electrode of the driving transistor DT and the power supply voltage line VDD.

Specifically, the micro-LED element may be connected to the drain electrode and a power supply electrode. A first end of the micro-LED element may be connected to the drain electrode of the driving transistor DT. A second end of the micro-LED element may be connected to the power supply voltage line VDD. A line supplying the power supply voltage line VDD may be formed in a different layer from the driving transistor DT, and in this case, the power supply electrode and the power supply voltage line VDD may be connected through a via Via2.

Although the present invention has been described above with reference to the exemplary drawings, the present invention is not limited by the embodiments and drawings disclosed in the specification, and it is apparent that various modifications can be made by those skilled in the art within the scope of the technical spirit of the present invention. In addition, even when the operational effects according to the configuration of the present invention have not been explicitly described in the description of the embodiments of the present invention, it goes without saying that the effects predictable by the corresponding configuration should be recognized.

1. A method of manufacturing a light emitting diode (LED) display device, the method comprising:
(a) forming a first insulating layer on a substrate on which a first electrode layer and a second electrode layer are disposed to be spaced apart from each other;
(b) aligning a first micro-LED element on the first insulating layer corresponding to a region between the first electrode layer and the second electrode layer so that a longitudinal direction of the first micro-LED element is parallel to a plane of the substrate;
(c) forming a second insulating layer on the substrate on which the first micro-LED element is aligned;
(d) aligning a second micro-LED element on the second insulating layer corresponding to the region between the first electrode layer and the second electrode layer so that a longitudinal direction of the second micro-LED element is parallel to the plane of the substrate; and
(e) patterning the first insulating layer and the second insulating layer so that the first electrode layer and the second electrode layer are exposed, and then depositing a first connection electrode to one ends of a plurality of stacked micro-LED elements and depositing a second connection electrode to the other ends to connect the plurality of stacked micro-LED elements to the first electrode layer and the second electrode layer.

2. The method of claim 1, wherein in the operation (a), the substrate has the first electrode layer and the second electrode layer that are disposed to be spaced apart from each other on a transistor disposed in each of a plurality of pixel regions defined by crossing data lines and gate lines.

3. The method of claim 1, wherein the operation (b) includes:
(b1) forming one or more first grooves in a region between the first electrode layer and the second electrode layer of the first insulating layer; and
(b2) aligning one first micro-LED element in one first groove so that the longitudinal direction of the first micro-LED element is parallel to the plane of the substrate.

4. The method of claim 1, wherein the operation (d) includes:
(d1) forming one or more second grooves in a region between the first electrode layer and the second electrode layer of the second insulating layer; and
(d2) aligning one second micro-LED element in one second groove so that the longitudinal direction of the second micro-LED element is parallel to the plane of the substrate.

5. The method of claim 1, wherein each of the operation (b) and the operation (d) includes aligning the micro-LED element by supplying a fluid including the plurality of micro-LED elements on the substrate and applying an electrical signal to the first electrode layer and the second electrode layer to generate an electric field.

6. The method of claim 1, wherein forming an insulating layer and aligning the micro-LED element on the insulating layer corresponding to the region between the first electrode layer and the second electrode layer so that the longitudinal direction of the micro-LED element is parallel to the plane of the substrate are performed one or more times between the operation (d) and the operation (e).

7. The method of claim 1, wherein the operation (e) includes:
(e1) applying photoresist on the substrate on which the plurality of stacked micro-LED elements are disposed and then removing portions of the photoresist corresponding to both ends of the plurality of micro-LED elements;
(e2) removing portions of the first insulating layer and the second insulating layer corresponding to the both ends of the plurality of micro-LED elements so that the first electrode layer and the second electrode layer are exposed;
(e3) depositing the first connection electrode to extend from the one ends of the plurality of micro-LED elements to the first electrode layer and depositing the second connection electrode to extend from the other ends to the second electrode layer to connect the one ends of the plurality of micro-LED elements to the first electrode layer and connect the other ends of the plurality of micro-LED elements to the second electrode layer; and
(e4) removing all of the first insulating layer, the second insulating layer, and the photoresist.

8. The method of claim 1, wherein the operation (e) includes:
(e1) applying first photoresist on the substrate on which the plurality of stacked micro-LED elements are disposed and then removing portions of the first photoresist corresponding to both ends of the plurality of micro-LED elements;
(e2) removing portions of the first insulating layer and the second insulating layer corresponding to the both ends of the plurality of micro-LED elements so that the first electrode layer and the second electrode layer are exposed and then removing the first photoresist;
(e3) depositing a connection electrode on the entire surface of the substrate on which the plurality of micro-LED elements are disposed to connect the ones of the plurality of micro-LED elements to the first electrode layer and connect the other ends of the plurality of micro-LED elements to the second electrode layer;
(e4) applying second photoresist on the substrate on which the connection electrode is deposited and applying the second photoresist on upper portions and side surfaces of the plurality of micro-LED elements; and
(e5) removing the first insulating layer, the second insulating layer, and the connection electrode from a portion where the second photoresist is not applied and then removing the remaining second photoresist, the first insulating layer, and the second insulating layer.

9. The method of claim 1, further comprising, after the operation (e), (f) arranging a partition wall including a metal layer on side surfaces of the plurality of stacked micro-LED elements.

10. The method of claim 9, further comprising, after the operation (f), (g) arranging a color conversion layer in which a color conversion particle is dispersed in at least one of upper portions, lower portions, and side surfaces of the plurality of stacked micro-LED elements and a gap between the plurality of stacked micro-LED elements.

11. A light emitting diode (LED) display device comprising:
a first electrode layer and a second electrode layer disposed to be spaced apart from each other on a substrate;
a plurality of micro-LED elements stacked in a longitudinal direction to be parallel to a plane of the substrate on the first electrode layer and the second electrode layer and stacked to be spaced apart from each other; and
a first connection electrode coupled to both ends of the plurality of micro-LED elements and extending from one ends of the plurality of micro-LED elements to the first electrode layer and a second connection electrode extending from the other ends of the plurality of micro-LED elements to the second electrode layer and connected to the second electrode layer.

12. The LED display device of claim 11, wherein the substrate includes a transistor disposed in each of a plurality of pixel regions defined by intersecting data lines and gate lines.

13. The LED display device of claim 11, wherein a partition wall including a metal layer is disposed on side surfaces of the plurality of stacked micro-LED elements.

14. The LED display device of claim 11, further comprising a color conversion layer in which a color conversion particle is dispersed in at least one of upper portions, lower portions, and side surfaces of the plurality of stacked micro-LED elements and a gap between the plurality of stacked micro-LED elements.

15. The LED display device of claim 11, wherein the micro-LED element has a nanowire shape.
